(19) United States
(12) Patent Application Publication
(10) Pub. No.: US 2024/0162106 A1
(43) Pub. Date: May 16, 2024

(54) BALL GRID ARRAY SEMICONDUCTOR DEVICE WITH THERMAL PADS AND PRINTED CIRCUIT BOARD THEREFOR

(71) Applicant: Western Digital Technologies, Inc., San Jose, CA (US)

(72) Inventors: Teng Sun, Shanghai (CN); Wei Xiao, Shanghai (CN); Hui Xu, Shanghai (CN); Chong Un Tan, Shanghai (CN); Fei Wang, Shanghai (CN)

(73) Assignee: Western Digital Technologies, Inc., San Jose, CA (US)

(21) Appl. No.: 18/222,362

(22) Filed: Jul. 14, 2023

Related U.S. Application Data
(60) Provisional application No. 63/425,359, filed on Nov. 15, 2022.

(51) Int. Cl. H01L 23/36; H01L 23/00; H01L 23/31; H01L 23/498; H01L 25/065; H10B 80/00

(52) U.S. Cl. CPC H01L 23/36; H01L 23/3128; H01L 23/49816; H01L 23/49822; H01L 23/49827; H01L 24/16; H01L 25/0657; H10B 80/00; H01L 24/32; H01L 24/73; H01L 2224/16227; H01L 2224/32225; H01L 2224/73204; H01L 2225/06506; H01L 2225/0651; H01L 2225/06562

(57) ABSTRACT

A semiconductor device incudes a substrate, a controller die on a top surface of the substrate, and a thermal spreader and outgas channel pad on a bottom surface of the substrate. The thermal spreader and outgas channel pad may be broken into a number of blocks separated by outgassing channels. The semiconductor device may be mounted on a printed circuit board using a solder shim. Materials outgassed from the solder shim when attaching the semiconductor device may escape through the outgassing channels.

### CLAIM OF PRIORITY

The present application claims priority from U.S. Provisional Patent Application No. 63/425,359, entitled “BALL GRID ARRAY SEMICONDUCTOR DEVICE WITH THERMAL PADS AND PRINTED CIRCUIT BOARD THEREFOR,” filed, Nov. 15, 2022, which is incorporated by reference herein in its entirety.

### BACKGROUND

The strong growth in demand for portable consumer electronics is driving the need for high-capacity storage devices. Non-volatile semiconductor memory devices are now widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computer SSDs, PDAs and cellular telephones.

While many varied packaging configurations are known, flash memory semiconductor packages may in general be assembled as system-in-a-package (SIP) or multichip modules (MCM), where a semiconductor controller die and a number of semiconductor memory dies are mounted and interconnected to an upper surface of substrate such as a printed circuit board.

During operation, the controller die generates heat which can adversely affect operation of the semiconductor package. As present-day packages are running faster and at higher frequencies, the problem of heat conduction away from the controller die is becoming more significant. Additionally, semiconductor packages are typically affixed to a printed circuit board using a solder paste. This solder paste may include a variety of fluids and chemicals which can outgas during the reflow process. These outgassed materials can result in delamination, popcorn effect where expanding steam in the outgassed materials causes bubbles and separation, and EOS (electrical overstress) where delamination or separation reduces the ability of the solder joint to transmit voltages. In addition to adversely affecting the strength and integrity of the solder bond, these effects can also negatively impact heat dissipation away from the semiconductor package.

### DESCRIPTION OF THE DRAWINGS

FIG. 1 is a flowchart of the overall assembly process of a semiconductor device according to embodiments of the present technology.

FIG. 2 is a top view of a panel of substrates used in forming semiconductor devices according to embodiments of the present technology.

FIG. 3 is an edge view of a substrate during assembly according to an embodiment of the present technology.

FIG. 4 is a top view of a substrate during assembly according to an embodiment of the present technology.

FIG. 5 is a bottom view of a substrate during assembly according to an embodiment of the present technology.

FIG. 6 is an edge view of a substrate at a further assembly stage according to an embodiment of the present technology.

FIG. 7 is a bottom perspective edge view of a substrate at a further assembly stage according to an embodiment of the present technology.

FIG. 8 is an edge view of a semiconductor device during assembly according to an embodiment of the present technology.

FIG. 9 is a top perspective view of a semiconductor device during assembly according to an embodiment of the present technology.

FIG. 10 is an edge view of a completed semiconductor device according to an embodiment of the present technology.

FIG. 11 is a bottom perspective view of a completed semiconductor device according to an embodiment of the present technology.

FIG. 12 is an edge view of a semiconductor device according to an alternative embodiment of the present technology.

FIG. 13 is an edge view of a semiconductor device according to a further alternative embodiment of the present technology.

FIG. 14 is an edge view of a printed circuit board for use with the semiconductor device according to an embodiment of the present technology.

FIG. 15 is a top perspective view of a printed circuit board for use with the semiconductor device according to an embodiment of the present technology.

FIG. 16 is an edge view of a semiconductor device positioned for mounting on a printed circuit board according to an embodiment of the present technology.

FIG. 17 is an edge view of a semiconductor device seated on a printed circuit board according to an embodiment of the present technology.

FIG. 18 is an edge view of a semiconductor device mounted to a printed circuit board after reflow according to an embodiment of the present technology.

### DETAILED DESCRIPTION

The present technology will now be described with reference to the figures, which in embodiments, relate to a BGA (ball grid array) semiconductor device including a substrate, a controller die on a top surface of the substrate, and a thermal spreader and outgas channel pad on a bottom surface of the substrate. The heat spreader and outgas channel pad may be broken into a number of blocks separated by outgassing channels. The thermal spreader and outgas channel pad performs a number of functions. For example, the pad effectively conducts heat from the controller die which is dissipated through the pad to a printed circuit board on which the semiconductor device is mounted. Second, the heat spreader pad provides stronger bonding to the printed circuit board than solder bumps alone. Third, the strong bonding of the BGA package to the host device allows a reduction in the number of solder balls, which conventionally included dummy solder balls to add bonding strength. Fourth, the outgassing channels between blocks in the thermal spreading pad define channels which allow escape of outgassed materials during reflow.

The BGA semiconductor device may be mounted on a PCB using a solder shim. In addition to providing a stronger bond between the BGA semiconductor device and the PCB than solder bumps alone, the solder shim reduces the amount of solder paste that gets printed onto the PCB for receiving solder balls, as well as a reduction in the outgassing that such solder paste generates.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is 0.15 mm or alternatively ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

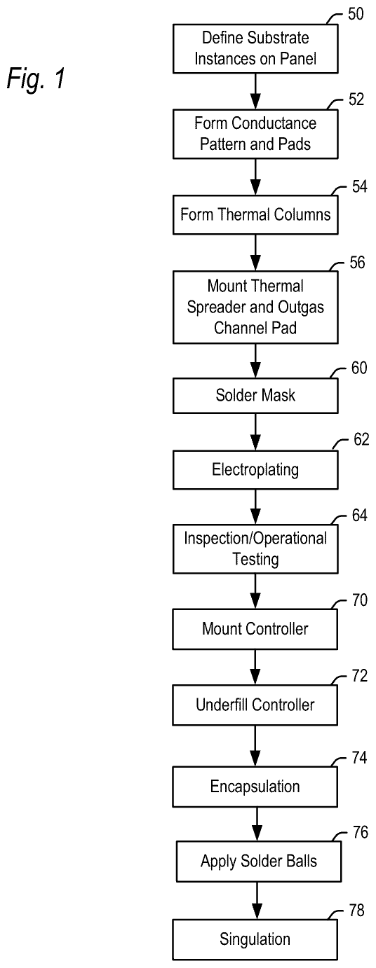

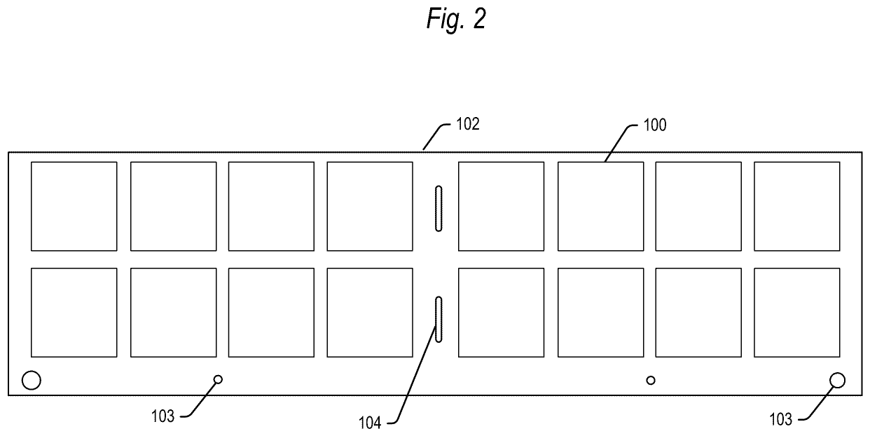

An embodiment of the present technology will now be explained with reference to the flowchart of FIG. 1 and the edge, top, bottom and perspective views of FIGS. 2 through 18. The assembly of a semiconductor device according to the present technology begins with a plurality of substrates 100 formed contiguously on a panel 102 in step 50 as shown in FIG. 2. FIG. 2 shows one representation of a panel 102 of substrates 100, though panel 102 may have a wide variety of other configurations and numbers of substrates 100 in further embodiments. Fiducial marks 104 are provided on the substrate panel 102 to allow machine vision alignment of the substrate panel in a processing tool. Again, the fiducial marks are by way of example only and may vary in other substrate panels.

The substrate 100 is an example of a chip carrier medium provided to transfer signals, data and/or information between one or more semiconductor dies mounted on the chip carrier medium and a host device as explained below. Other examples of chip carrier mediums may be used, including a printed circuit board (PCB), a leadframe or a tape automated bonded (TAB) tape. The substrate may be formed of one or more core layers, each sandwiched between conductive layers. The conductive layers may be formed of copper or copper alloys, plated copper or plated copper alloys, Alloy 42 (42Fe/58Ni), copper plated steel, or other metals and materials suitable for use on substrate panels. The one or more core layers may be formed of various dielectric materials such as for example, polyimide laminates, epoxy resins including FR4 and FR5, bismaleimide triazine (BT), and the like. The one or more core layers may be ceramic or organic in alternative embodiments.

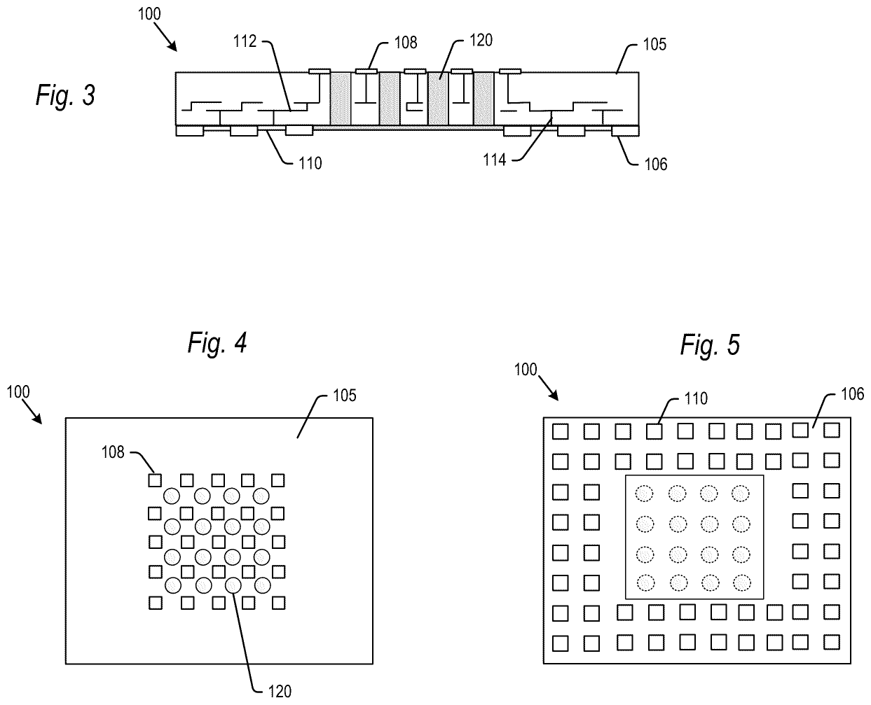

The substrate 100 may include a first, or top, major planar surface 105 and a second, or bottom, major planar surface 106. The external conductive layers on the first and second major planar surfaces 105, 106 may be etched into conductance patterns comprising electrical connectors in step 52. In one example shown in FIGS. 3-5, the electrical connectors in the first major surface 105 may include contact pads 108 for physically and electrically attaching a controller (or other) die to the substrate 100 as explained below. The electrical connectors in the second major surface 106 may include contact pads 110 for physically and electrically attaching the substrate 100 to a host device such as a printed circuit board as explained below.

One or more intermediate conductive layers within the substrate 100 may be etched with conductive traces 112 prior to assembly into the substrate 100. Once assembled, these internal conductive traces 112 may be coupled with each other, and the contact pads 108, 110 on the top and bottom major surfaces 105, 106, with internal vias 114. The internal traces 112 and vias 114 together function as RDLs (redistribution layers) to electrically redistribute the contact pads 108 on first major planar surface 105 to the contact pads 110 on the second major planar surface 106. The pattern and number of internal conductive layers, contact pads 108, contact pads 110, electrical traces 112 and vias 114 are provided by way of example only and each may vary in further embodiments.

In accordance with aspects of the present technology, thermal columns 120 may be formed in step 54 between the top and bottom major planar surfaces 105, 106 as shown in FIGS. 3-5. The thermal columns 120 may be copper-filled vias, though they may be formed of other heat conducting materials in addition to or instead of copper. The diameter and number of thermal columns 120 may vary in embodiments but in general, there may be enough thermal columns to cover the length and width of the thermal spreader and outgas channel pads, explained below. The thermal columns 120 may be spaced from each other sufficient to allow the thermal columns 120 to be interspersed with contact pads 108 as shown in FIG. 4.

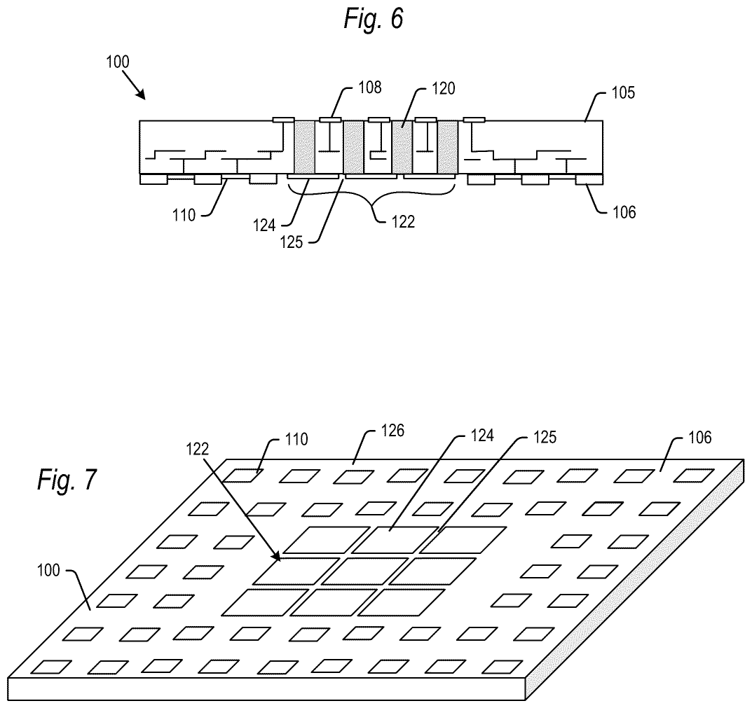

In accordance with further aspects of the present technology, a thermal spreader and outgas channel pad 122 may be formed in the bottom conductive layer of the substrate 100 in step 56 and as shown in the edge and bottom perspective view of FIGS. 6 and 7. The thermal spreader and outgas channel pad 122, also referred to herein as TSOC pad 122, is comprised of a number of discrete blocks 124, each spaced from each other to define outgassing channels 125 between the blocks 124. Each block 124 in TSOC pad 122 may be formed of copper, though blocks 124 may be formed of other heat conducting materials in addition to or instead of copper. In further embodiments, each block 124 of the TSOC pad 122 may be affixed to the bottom conductive layer of the substrate 100. In such embodiments, each block 124 may be mounted to the substrate as by solder or a thermally conductive adhesive.

Each block 124 may be identical to each other, with a thickness of between 10 and 50 μm, such as for example 10 to 20 μm, and each may have a length and width of 10 to 20 mm. It is understood that the thicknesses, lengths and/or widths of each block 124 may vary from this in further embodiments. The figures show nine blocks 124 evenly spaced from each other in rows and columns to define the outgassing channels 125 therebetween. There may be more or less than nine blocks 124 in further embodiments. There may be as few as two blocks, defining a single outgassing channel 125 centrally therebetween. The individual blocks 124 are shown as being square or rectangular though the blocks 124 may other shapes in further embodiments including for example circular or oval.

Where blocks 124 are square or rectangular, the one or more outgassing channels 125 may be linear with a width of between 2 and 50 μm, such as for example 5 to 10 μm, but the width of each outgassing channel 125 may be greater or lesser than that in further embodiments. The thermal columns 120 and TSOC pad 122 form part of a heat conduction path for carrying heat away from a controller semiconductor die mounted on the substrate 100 as explained below.

The substrate 100 may undergo a variety of further processing steps, including solder masking (step 60), electroplating of exposed contact pads (step 62) on surfaces 105, 106, and inspection and operational testing (step 64). At least some of the above-described steps may be performed in different orders, and additional or alternative processing steps are contemplated.

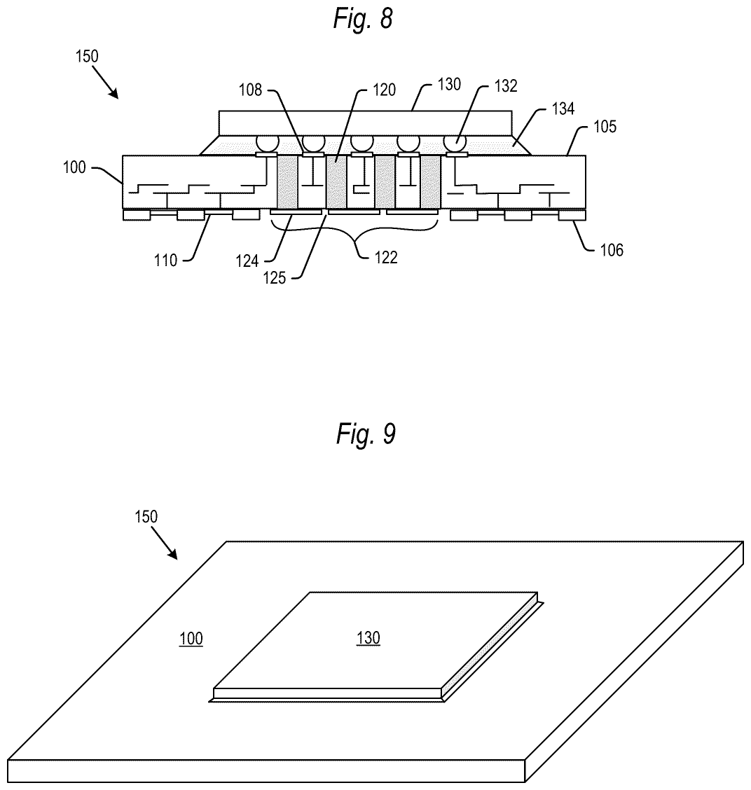

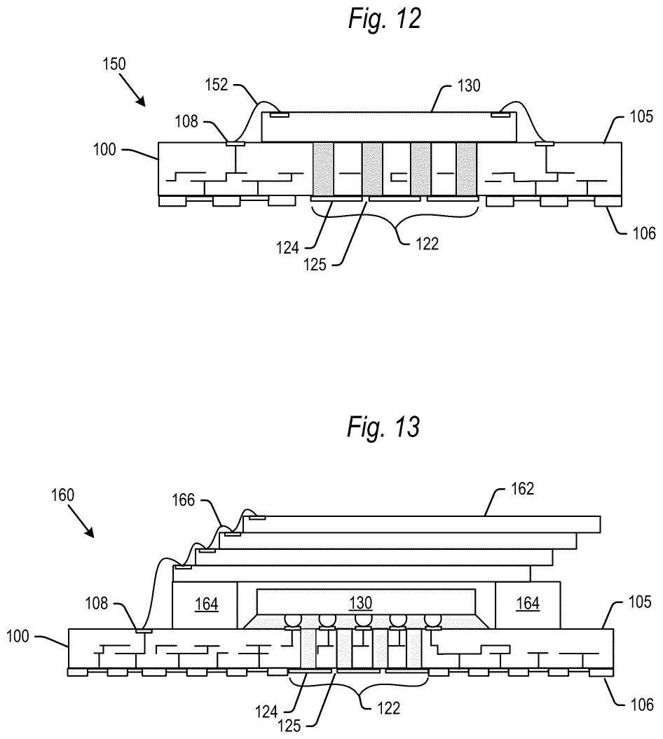

In step 70, a semiconductor die 130 may be mounted to the first major planar surface 105 of substrate 100 as shown for example in FIGS. 8 and 9. The combination of the controller die 130 on substrate 100 may be referred to herein as a semiconductor device 150. The semiconductor die 130 is typically described hereinafter as being a controller semiconductor die such as for example an ASIC used to control read/write operations for a group of semiconductor memory dies as explained below. However, it is understood that the semiconductor die 130 may be other types of semiconductor dies in further embodiments, including a semiconductor memory die. The semiconductor die 130 may be flip-chip mounted to contact pads 108 on the top major planar surface 105 using solder balls 132 to physically and electrically couple the semiconductor die 130 to substrate 100. As explained below with respect to FIG. 12, the semiconductor die 130 may be affixed to substrate 100 by other methods in further embodiments.

To the extent a space exists between the controller die 130 and the top major planar surface 105, that space may be under filled with a material 134 in step 72. The underfill material 134 may be thermally conductive and electrically insulating, such as for example various thermally conductive polymers, or dielectric solder alloy. The underfill material 134 may be omitted in further embodiments.

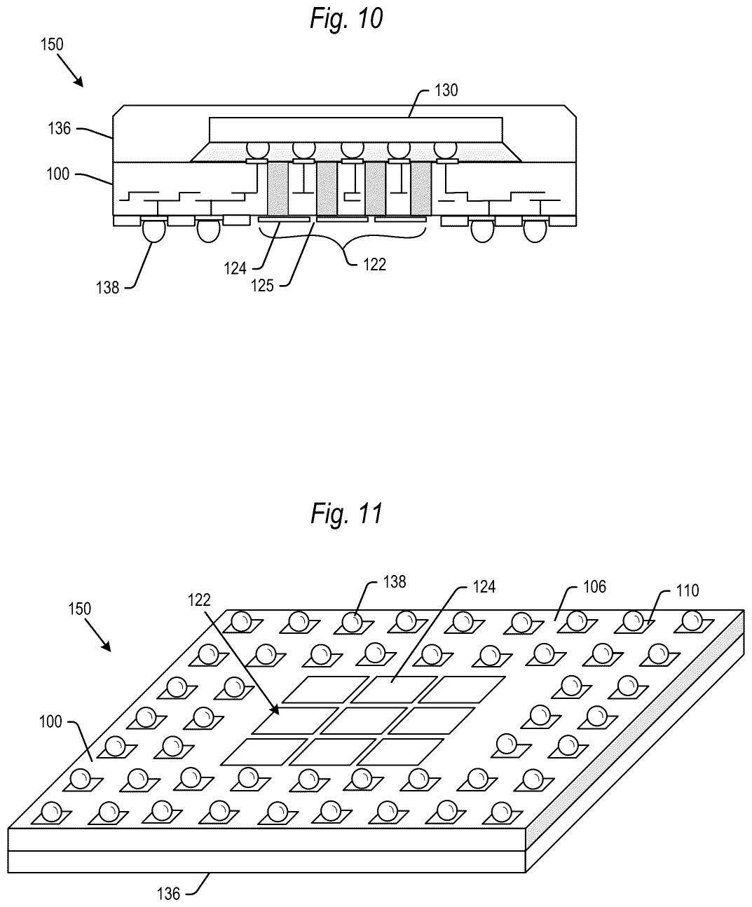

In step 74, the panel 102 of semiconductor devices 150 may be encapsulated in a mold compound 136 as shown in the edge and bottom perspective views of FIGS. 10 and 11. Mold compound 136 may include for example solid epoxy resin, Phenol resin, fused silica, crystalline silica, carbon black and/or metal hydroxide. Other mold compounds are contemplated. The mold compound 136 may be applied by various known processes, including by FFT (flow free thin) molding, compression molding, transfer molding or injection molding techniques. In step 76 solder balls 138 may be applied to the bottom contact pads 110 as shown for example in FIGS. 10 and 11.

After assembly and encapsulation of the semiconductor devices 150, the semiconductor devices 150 may be singulated from each other and panel 102 in step 78 to form individual finished semiconductor devices 150, such as the one shown in the edge and bottom perspective views of FIGS. 10 and 11. The semiconductor devices 150 may be singulated by any of a combination of cutting methods including sawing, water jet cutting, laser cutting, water guided laser cutting, dry media cutting, and diamond coating wire cutting.

In embodiments described above, the controller semiconductor die 130 is flip-chip mounted to the substrate 100. In a further embodiment shown in the edge view of FIG. 12, the controller die 130 may be mounted to substrate 100 via bond wires 152 formed between die bond pads on the controller die 130 and contact pads 108 on the top major planar surface 105 of substrate 100. Bond wires 152 may be formed in a known manner using a wire bond capillary (not shown) off of one or more edges of the controller die 130.

In embodiments described above, the semiconductor device 150 comprises a controller die 130 mounted to a substrate 100. The semiconductor device 150 may be mounted on a host device such as a printed circuit board (PCB) for controlling a group of memory dies also mounted on the PCB as explained below. In a further embodiment, the memory dies may be packaged together with the controller die 130 on substrate 100. Such embodiment will now be described with reference to the edge view of FIG. 13.

FIG. 13 shows a semiconductor device 160 including a substrate 100 and a controller die 130 assembled together as described above. The controller die 130 may be flip-chip mounted to the substrate 100 as shown in FIG. 13, or the controller die 130 may be wire bonded to the substrate 100 as shown in FIG. 12. This embodiment may further include one or more semiconductor memory dies 162 also mounted on substrate 100. In one embodiment, the semiconductor memory dies 162 may be spaced from the substrate 100 above the controller die 130 by spacer blocks 164. In further embodiments, the memory dies 162 may be directly affixed to the upper planar surface 105 of substrate 100, next to the controller die 130.

The semiconductor memory dies 162 may for example be 2D NAND flash memory or 3D BiCS (Bit Cost Scaling), V-NAND or other 3D flash memory, but other types of dies 162 may be used. These other types of semiconductor dies include but are not limited to RAM such as an SDRAM, DDR SDRAM, LPDDR and GDDR. Where multiple semiconductor memory dies 162 are included, the semiconductor dies 162 may be stacked atop each other in an offset stepped configuration to form a die stack. The number of dies 162 shown in the stack is by way of example only, and embodiments may include different numbers of semiconductor dies, including for example 1, 2, 4, 8, 16, 32 or 64 dies. There may be other numbers of dies in further embodiments. The one or more dies may be affixed to the substrate and/or each other using a die attach film.

The semiconductor memory dies 162 may be electrically interconnected to each other and to the substrate 100 using bond wires 166. Bond wires 166 may connect like-channel bond pads on respective dies 162 to each other down the stack, and then bond to contact pads 108 on first major planar surface 105 of substrate 100. The semiconductor dies 162 may be electrically interconnected to each other and the substrate 100 by other methods in further embodiments, including by through-silicon vias (TSVs) or flip-chip bonding.

Other electronic components may be mounted on the top and/or bottom major planar surfaces 105, 106 in further embodiments. Such electronic components may include one or more passive components such as for example one or more capacitors, resistors and/or inductors, though other components are contemplated.

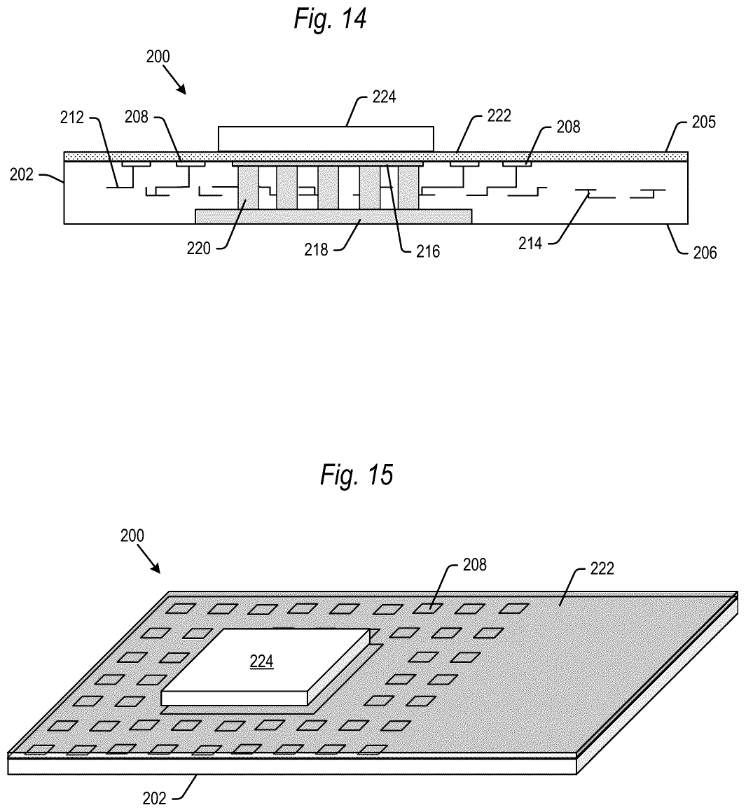

Upon completion, the semiconductor devices 150/160 may be mounted to a host device such as a printed circuit board. FIGS. 14 and 15 are edge and top perspective views of a printed circuit board 200 for use with either of the semiconductor devices 150 and 160 described above. The PCB 200 may be formed of one or more core layers, each sandwiched between conductive layers. The conductive layers may be formed of copper or copper alloys, plated copper or plated copper alloys, Alloy 42 (42Fe/58Ni), copper plated steel, or other metals and materials suitable for use on substrate panels. The one or more core layers may be formed of various dielectric materials such as for example, polyimide laminates, epoxy resins including FR4 and FR5, bismaleimide triazine (BT), and the like. The one or more core layers may be ceramic or organic in alternative embodiments.

The PCB 200 may include a base 202 having a first, or top, major planar surface 205 and a second, or bottom, major planar surface 206. The external conductive layers on the first and second major planar surfaces 205, 206 may be etched into conductance patterns comprising electrical connectors. In one example shown in FIGS. 14-15, the electrical connectors in the first major surface 205 may include contact pads 208 for physically and electrically attaching the semiconductor device 150/160 to the PCB 200 as explained below. One or more intermediate conductive layers within the PCB 200 may be etched with conductive traces 212 prior to assembly into the PCB 200. Once assembled, these internal conductive traces 212 may be coupled with each other and the contact pads 208 with internal vias 214. The pattern and number of internal conductive layers, contact pads 208, electrical traces 212 and vias 214 are provided by way of example only and may vary in further embodiments.

The PCB 200 may further include top and bottom thermal plates 216 and 218 formed in the conductive layers of the top and bottom major planar surfaces 205, 206 as shown in FIG. 14. The thermal plates 216, 218 may be 10 to 50 μm thick and 20 to 50 mm in length and width. In embodiments, the bottom plate 218 may have a greater length and/or width than the top plate 216, and the bottom thermal plate 218 may be thicker than the top thermal plate 216. It is understood that the thickness, length and/or width of the thermal plates 216 and 218 may vary in further embodiments. Thermal columns 220 may be formed between the top and bottom thermal plates 216, 218 as shown in FIG. 14. The thermal columns 220 may be copper-filled vias, though they may be formed of other heat conducting materials in addition to or instead of copper. The diameter and number of thermal columns 220 may vary in embodiments but in general, there may be enough thermal columns to cover the length and width of at least the smaller of the thermal plates 216, 218.

Conventionally, solder paste may be applied using a screen onto portions of the top major planar surface 205 of PCB 200 in the areas of the PCB 200 which receive solder balls. On reflow, outgassing of such solder paste can result in delamination, a popcorn effect and/or EOS (electrical overstress) as discussed in the Background section. In accordance with further aspects of the present technology, the problems associated with outgassing may be alleviated by omitting application of the solder paste to the PCB 200. In particular, a layer of flux 222 may be printed or otherwise applied to the top major planar surface 205 of the PCB 200. Flux layer 222 may be a rosin flux from pinesap, though other types of flux may be used. The flux removes any oxide films which may otherwise form when the semiconductor device 150/160 is joined to PCB 200 and affixed in a reflow process as explained below.

The PCB 200 further includes a solder shim 224 tacked on the upper surface of flux layer 222. The solder shim 224 may have an area at least as great as the area of the TSOC pad 122, and a thickness of, for example, 20 to 100 μm, but the thickness of the solder shim 224 may vary in further embodiments.

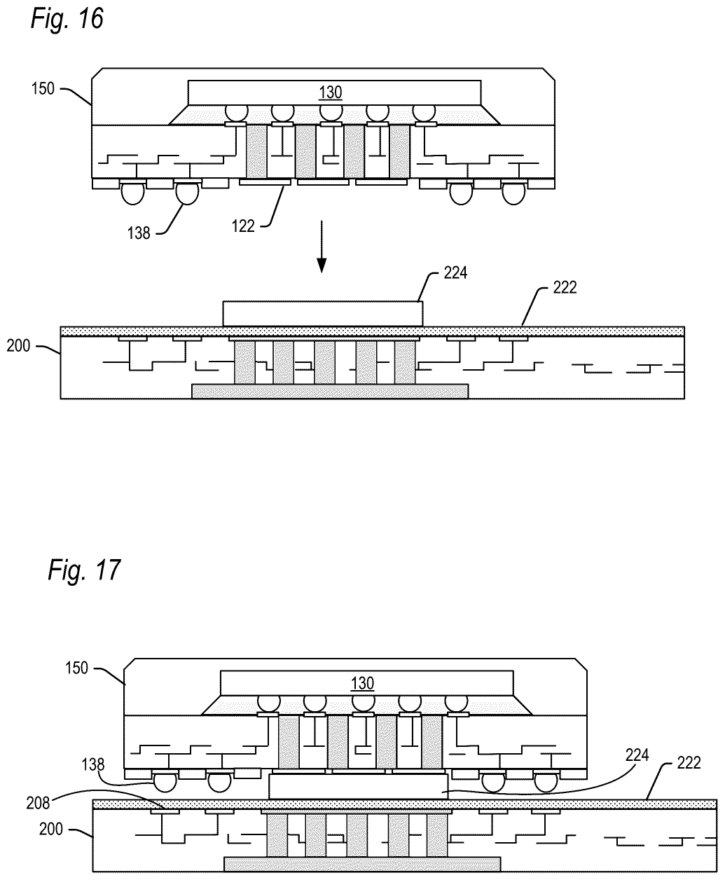

Referring now to the edge views of FIGS. 16 and 17, the semiconductor device (the semiconductor device 150 in this example) may be positioned over the PCB 200 with the TSOC pad 122 centered over the solder shim 224 as shown in FIG. 16. From there, the semiconductor device 150 may be lowered onto the PCB 200 as shown in FIG. 17 so that semiconductor device 150 is supported on the PCB 200 by the TSOC pad 122 lying in contact with the solder shim 224. As shown, in this position, the solder balls 138 of semiconductor device 150 may be spaced above the contact pads 208 of the PCB 200.

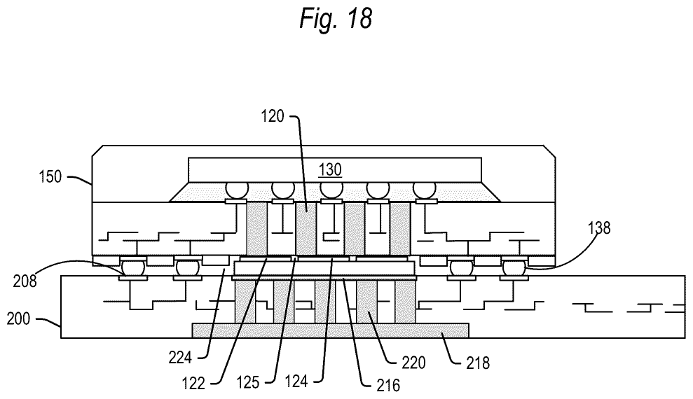

Thereafter, device 150 and PCB 200 may be heated in a reflow process. In one example, the reflow process may be performed at 220 to 250° C., for a period of 40 to 80 seconds. However, it is understood that both the temperature range and time duration for the reflow process may vary in further embodiments. During the reflow process, the flux layer 222 will liquefy and evaporate, and the solder shim 224 will melt, evaporate and/or otherwise become thinner as shown in the edge view of FIG. 18. Thinning of the solder shim 224 lowers the semiconductor device 150 onto the PCB 200 so that the solder balls 138 reach the contact pads 208. It is noted that the solder shim 224 may have a lower melting/evaporation temperature than solder balls 138 so that the solder balls 138 do not melt until the solder shim 224 has thinned and the solder balls 138 contact their respective contact pads 208. Once in contact with the contact pads 208, the solder balls 138 may soften and diffuse with contact pads 208 to electrically couple the semiconductor device 150 to the PCB 200.

During the reflow process, the blocks 124 of the TSOC pad 122 will bond to the softened solder shim 224. Bonding of the semiconductor device 150 PCB 200 using the TSOC pad 122 and solder shim 224 in accordance with the present technology has several advantages. For example, the TSOC pad 122 and solder shim 224 form part of a thermal conduction path effectively removing heat generated by the controller die 130 in the semiconductor device 150. As noted, controller semiconductor dies generate large amounts of heat, especially when operating at the higher frequencies of present-day memory devices. In accordance with aspects of the present technology, a thermal conduction path is provided from the controller die 130 to the PCB 200 via thermal columns 120, TSOC pad 122, solder shim 224, thermal plates 216, 218 and thermal columns 220. Each of these components may lie in direct contact with its neighboring component to provide a thermal conduction path effectively removing heat from the controller die 130 and semiconductor device 150.

Additionally, as the solder shim 224 melts, it will outgas material such as chemicals and/or vapor. It is an advantage of the present technology that these outgassed chemicals and vapors may be effectively escape from the interface between the TSOC pad 122 and the solder shim 224 by the outgassing channels 125 between the blocks 124 of the TSOC pad 122. This effectively alleviates the delamination, popcorn effect and other problems associated with conventional soldering of semiconductor devices to a printed circuit boards.

In a further advantage, the large surface area of the TSOC pad 122 and solder ship 224, together with removal of outgassed materials through channels 125, provides a stronger mechanical bonding of the semiconductor device 150/160 to the printed circuit board 200 than is found in conventional designs. Not only does this increase yields during board level reliability mechanical stress testing, but it also allows reduction in the number of solder balls used between the semiconductor device 150 in the printed circuit board 200. In particular, conventional designs employed dummy solder balls to provide additional bonding strength. These dummy solder connections can be omitted through use of the present technology, thereby reducing the number of solder balls and the associated costs, as well as potential reducing the overall footprint of the semiconductor device 150.

In summary, in one example, the present technology relates to a semiconductor device, comprising: a substrate; a semiconductor die mounted on a first side of the substrate; electrical interconnections electrically coupling the semiconductor die to the substrate; and a pad mounted on a second side of the substrate opposite the first side, the pad comprising a plurality of discrete thermally conductive blocks, the blocks spaced from each other to define one or more outgassing channels between the blocks, the pad configured to conduct heat away from the semiconductor die and the pad configured to channel outgassed material away from the semiconductor device through the one or more outgassing channels.

In another example, the present technology relates to a semiconductor device configured to mount on a solder shim of a printed circuit board, the semiconductor device, comprising: a substrate; a semiconductor die mounted on a first side of the substrate; and a pad mounted on a second side of the substrate opposite the first side and configured to mount on the solder shim, the pad comprising a plurality of discrete thermally conductive blocks, the blocks spaced from each other to define one or more outgassing channels between the blocks; wherein the one or more outgassing channels are configured to provide a pathway for escape of outgassed material when the pad of the semiconductor device is attached to the solder shim of the printed circuit board.

In another example, the present technology relates to a semiconductor device, comprising: a substrate; a semiconductor die mounted on a first side of the substrate; electrical interconnections electrically coupling the semiconductor die to the substrate; means for conducting heat from the semiconductor die; and means for allowing escape of outgassed material when the semiconductor device is affixed to a host device.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor device, comprising:
a substrate;
a semiconductor die mounted on a first side of the substrate;
electrical interconnections electrically coupling the semiconductor die to the substrate; and
a pad mounted on a second side of the substrate opposite the first side, the pad comprising a plurality of discrete thermally conductive blocks, the blocks spaced from each other to define one or more outgassing channels between the blocks, the pad configured to conduct heat away from the semiconductor die and the pad configured to channel outgassed material away from the semiconductor device through the one or more outgassing channels.

2. The semiconductor device of claim 1, further comprising a plurality of thermal columns positioned between the semiconductor die on the first side of the substrate and the pad on the second side of the substrate, wherein the plurality of thermal columns are configured to conduct heat away from the semiconductor die.

3. The semiconductor device of claim 1, wherein the substrate comprises first and second conductive layers, and wherein the thermal pad is formed in one of the first and second conductive layers.

4. The semiconductor device of claim 1, wherein the thermal pad is affixed to a bottom surface of the substrate by one of a thermally conductive adhesive and solder.

5. The semiconductor device of claim 1, wherein the electrical interconnections comprise a first plurality of contact pads on the first surface of the substrate, the semiconductor device further comprising a plurality of thermal columns extending between the first and second sides of the substrate, wherein the plurality of thermal columns are configured to conduct heat away from the semiconductor die, and wherein the plurality of thermal columns are interspersed with the first plurality of contact pads on the first side of the semiconductor device.

6. The semiconductor device of claim 1, further comprising a second plurality of contact pads on the second side of the substrate, wherein the second plurality of contact pads are configured to electrically couple the semiconductor device to a host device.

7. The semiconductor device of claim 6, wherein the pad is further configured to physically couple the semiconductor device to the host device.

8. The semiconductor device of claim 1, wherein the plurality of thermally conductive blocks are arranged in rows and columns of blocks defining a plurality of outgassing channels.

9. The semiconductor device of claim 1, wherein the plurality of thermally conductive blocks comprise nine thermally conductive blocks defining a plurality of outgassing channels.

10. The semiconductor device of claim 1, further comprising molding compound for encapsulating the semiconductor die and electrical interconnections.

11. The semiconductor device of claim 1, wherein the semiconductor die comprises a controller die.

12. The semiconductor device of claim 11, further comprising one or more memory dies mounted to the substrate above or to the side of the controller die.

13. A semiconductor device configured to mount on a solder shim of a printed circuit board, the semiconductor device, comprising:
a substrate;
a semiconductor die mounted on a first side of the substrate; and
a pad mounted on a second side of the substrate opposite the first side and configured to mount on the solder shim, the pad comprising a plurality of discrete thermally conductive blocks, the blocks spaced from each other to define one or more outgassing channels between the blocks;
wherein the one or more outgassing channels are configured to provide a pathway for escape of outgassed material when the pad of the semiconductor device is attached to the solder shim of the printed circuit board.

14. The semiconductor device of claim 13, wherein the pad of the semiconductor device is thermally conductive to conduct heat away from the semiconductor die.

15. The semiconductor system of claim 13, further comprising a set of thermal columns in the substrate of the semiconductor device, the solder columns configured to conduct heat from the semiconductor die.

16. The semiconductor device of claim 13, further comprising a plurality of solder balls on the second surface of the substrate, the plurality of solder balls configured to mate with contact pads of the printed circuit board upon reflow of the solder shim.

17. The semiconductor device of claim 13, wherein the pad is configured to physically couple the semiconductor device to the printed circuit board at the solder shim.

18. The semiconductor device of claim 13, wherein the plurality of thermally conductive blocks are arranged in rows and columns of blocks defining a plurality of outgas sing channels.

19. The semiconductor device of claim 13, wherein the semiconductor die comprises a controller die.

20. A semiconductor device, comprising:
a substrate;
a semiconductor die mounted on a first side of the substrate;
electrical interconnections electrically coupling the semiconductor die to the substrate;
means for conducting heat from the semiconductor die; and
means for allowing escape of outgassed material when the semiconductor device is affixed to a host device.
